(19) United States
(12) Patent Application Publication
(10) Pub. No.: US 2005/0136289 A1
(43) Pub. Date: Jun. 23, 2005

(54) White organic light emitting device

(76) Inventors: Hye Yong Chu, Daejeon-shi (KR); Jeong Ik Lee, Suwon-shi (KR)

Correspondence Address: PIPER RUDNICK LLP, P. O. BOX 9271, RESTON, VA, 20195, US

(21) Appl. No.: 11/013,191

(22) Filed: Dec. 16, 2004

(30) Foreign Application Priority Data
Dec. 22, 2003 (KR) 2003-94755
Jun. 7, 2004 (KR) 2004-52214

(51) Int. Cl. H05B 33/14

(52) U.S. Cl. 428/690; 428/917; 428/212; 313/504; 313/506

(57) ABSTRACT

Provided is a white organic light emitting device capable of realizing characteristics of excellent color purity and high efficiency through structural simplification. The white organic light emitting device includes an emission layer, a hole blocking layer and an electron transport layer which are deposited between an anode and an cathode to which a bias is applied, wherein a host having a blue luminescence property and a first guest having any one of orange and red luminescence properties are doped into the emission layer, and a material having a green luminescence property is included in the electron transport layer.

### CROSS-REFERENCE TO RELATED APPLICATION

This application claims priority to and the benefit of Korean Patent Application Nos. 2003-94755, filed on Dec. 22, 2003, and 2004-52214, filed on Jul. 6, 2004, the disclosure of which is incorporated herein by reference in its entirety.

### BACKGROUND

1. Field of the Invention

The present invention relates to a white organic light emitting device used as a display device, and more particularly, to a white organic light emitting device capable of exhibiting characteristics of excellent color purity and high efficiency through structural simplification.

2. Discussion of Related Art

With development of the telecommunication industry, display devices have been rapidly increased in demand. Currently, the display device is required to be light in weight, thin in thickness and high in resolution. In line with this requirement, there have been developed display devices applying either liquid crystal display (LCD) properties or organic luminescence properties.

In order to make the display devices lightweight and thin, it is advantageous to use a plastic substrate being lightweight and thin, unlike existing display devices using a glass substrate.

Among the current display devices, an organic light emitting device has attracted attention as a next generation display device to use the plastic substrate, because it is most practical. Hence, an intensive study has been made of this organic light emitting device.

The organic light emitting device using an organic substance as a main component emits light by applying a current or a voltage to a cathode and an anode which are formed on both ends of an emission layer, respectively. In general, in order to obtain better luminescence properties, the organic light emitting device makes use of a multi-layer structure where a hole injection layer and/or a hole transport layer, and an electron transport layer and/or an electron injection layer are formed of materials helping injection of holes and electrons on both sides of the emission layer.

Conventionally, a monochromatic organic light emitting device is configured of a structure where an anode, an emission layer and a cathode are stacked on a substrate. This organic light emitting device can emit a variety of colors according to a kind of material composing the emission layer. In order to fabricate the organic light emitting device having white luminescence property, there is a method of stacking light emitting materials having luminescence properties of red (R), green (G) and blue (B) colors that are three primary colors of light, or stacking light emitting materials having a complementary color relationship. Thus, the white organic light emitting device may be sorted into a three-wavelength white organic light emitting device and a two-wavelength white organic light emitting device.

The conventional three-wavelength white organic light emitting device has a structure where an anode, an emission layer and a cathode are stacked on a substrate, wherein the emission layer is formed of light emitting materials of red (R), green (G) and blue (B) colors.

As set forth above, the three-wavelength white organic light emitting device using the light emitting materials of the three primary colors is excellent in color purity. However, because the light emitting materials of the red (R), green (G) and blue (B) colors are stacked, the three-wavelength white organic light emitting device shows a characteristic that stability of the colors is changed by a (electric) potential of energy according to current or time applied. When appropriate hole blocking layers are inserted between the layers of the light emitting materials, the color stability can be improved. In this case, the three-wavelength white organic light emitting device, however, has a complicated structure, thus causing problems of difficult fabrication and low efficiency.

Meanwhile, the conventional two-wavelength white organic light emitting device has a structure where an anode, an emission layer and a cathode are stacked on a substrate, wherein the emission layer is formed of light emitting materials having a complementary color relationship.

For the two-wavelength white organic light emitting device, a combination of the light emitting materials having the complementary color relationship, for example, the light emitting materials of a sky blue color and a red color, or a blue color and an orange color, is used. Therefore, the two-wavelength white organic light emitting device has easy fabrication and high efficiency compared to the three-wavelength white organic light emitting device. However, since the luminescence property-of a green color is low in comparison with those of red and blue colors, the two-wavelength white organic light emitting device has poor color reproduction. For these reasons, the two-wavelength white organic light emitting device is difficult to apply to applied fields where both the color purity and the color reproduction are required to be high, such as a display field, an illumination field, and so forth.

### SUMMARY OF THE INVENTION

The present invention is directed to implementation of a high efficiency of organic light emitting device having a white luminescence property by means of a simple structure using a single emission layer.

The present invention is also directed to implementation of a three-wavelength white organic light emitting device having high color reproduction by means of a simple structure using a single emission layer.

One aspect of the present invention is to provide a white organic light emitting device including: an anode and an cathode to which a bias is applied; and an emission layer into which a host having a blue luminescence property and a first guest exhibiting an orange or red luminescence property are doped, a hole blocking layer for confining holes in the emission layer, and an electron transport layer having a green luminescence property, wherein the emission layer, the hole blocking layer, and the electron transport layer are stacked between the anode and the cathode Preferably, the white organic light emitting device is additionally doped with a second guest capable of improving efficiency of the blue light emitting material.

Another aspect of the present invention is to provide a white organic light emitting device having a hole injection layer, a hole transport layer, an emission layer, a hole blocking layer, an electron transport layer and an electron injection layer which are deposited between an anode and a cathode on a substrate, including: a host having a blue luminescence property and a first guest having any one of orange and red luminescence properties doped into the emission layer; and a material with a green luminescence property formed in the electron transport layer.

Preferably, the blue light emitting material is any one of DPVBi and NPB having a band gap between 3.5 eV and 2.5 eV. The first guest is a red light emitting material, such as DCM, DCJTB, DADB, having a band gap between 2.2 eV and 1.7 eV, and is doped at a concentration between 0.01 and 5%.

Preferably, the second guest is any one of DSA-Amine and Perylene having a band gap between 3.5 eV and 2.5 eV, and is doped at a concentration between 0.1 and 10%.

The hole blocking layer is formed of a material having a level of highest occupied molecular orbital (HOMO) energy higher than the emission layer such as BCP, or TAZ, and is formed to a thickness smaller than a Forster energy transfer radius so as to enable Forster energy transfer of excitons from the emission layer to the electron transport layer.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a cross-sectional view for explaining a white organic light emitting device according to the present invention; and

FIG. 2 shows a luminescence spectrum of a white organic light emitting device fabricated according to the present invention.

### DETAILED DESCRIPTION OF PREFERRED EMBODIMENTS

Hereinafter, an exemplary embodiment of the present invention will be described in detail. However, the present invention is not limited to the embodiments disclosed below, but can be implemented in various types. Therefore, the present embodiment is provided for complete disclosure of the present invention and to fully inform the scope of the present invention to those ordinarily skilled in the art.

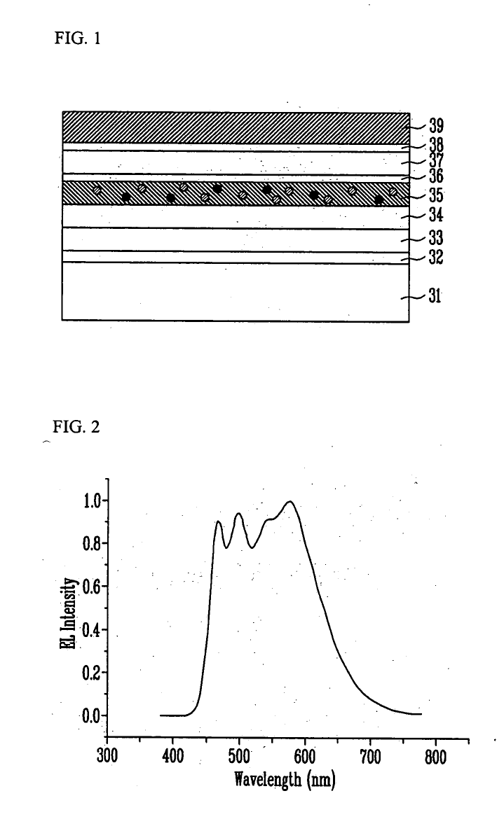

FIG. 1 is a cross-sectional view for explaining a white organic light emitting device according to the present invention.

An anode 32 of a transparent electrode material is formed on a substrate 31 made of transparent grass, quartz, or plastic. A hole injection layer (HIL) 33 helping injection of holes is formed on the anode 32. A hole transport layer (HTL) 34 is formed on the hole injection layer 33, wherein the HTL 34 causes the holes to have good mobility and to facilitate transportation to an emission layer 35.

On the HTL 34 is formed the emission layer 35 which forms a blue light emitting material as a host and into which a first guest capable of exhibiting an orange or red luminescence property is doped. Meanwhile, a second guest may be additionally doped into the emission layer 35, wherein the second guest is capable of improving efficiency of the blue light emitting material.

A hole blocking layer (HBL) 36 for confining the holes in the emission layer 35 is formed on the emission layer 35. An electron transport layer (ETL) 37, which has a green luminescence property and permits the electrons to be efficiently transported into the emission layer 35, is formed on the HBL 36.

An electron injection layer (EIL) 38 is formed on the ETL 37, and a cathode 39 is formed in a desired region on the EIL 38.

Next, a method of fabricating the white organic light emitting device will be described.

An anode 32 is formed on a substrate 31 made of transparent glass, quartz or plastic. The anode 32 is formed of a transparent electrode material which has a high conductivity and a high work function, such as ITO (Indium Tin Oxide), IZO (Indium Zinc Oxide) etc, and is subjected to patterning after depositing the transparent electrode material.

An HIL 33 is formed on the anode 32 to a thickness from about 10 nm to about 50 nm by means of a material helping injection of the holes such as MTDATA (4,4′,4″-tris[N,-(3-methylphenyl)-N-phenylamino] triphenylamine), CuPc (copper phthalocyanine), PEDOT/PSS (polyethylenedioxythiphene/polystyrenesulphonate), etc.

An HTL 34, which causes the holes to have good mobility and to facilitate transportation to the emission layer 35, is formed on the HIL 33 to a thickness from about 10 nm to about 100 nm. Preferably, the HTL 34 is formed of a material having good hole mobility such as TPD (N, N′-diphenyl-N, N′-bis93-methylphenyl)-1,1′-biphenyl-4, 4′-diamine), NPB (4, 4′-bis[N-1-naphthyl-1-1-)-N-phenyl-amino]-biphenyl), etc.

An emission layer 35, which forms a blue light emitting material as a host and into which a first guest capable of exhibiting an orange or red luminescence property is doped, is formed on the HTL 34. A second guest, which is capable of enhancing the efficiency of a blue light emitting material, may be additionally doped. The emission layer 35 can be deposited at a desired speed, and the doping is carried out by a process of adjusting the deposited speed and simultaneously depositing. The emission layer 35 is preferably formed to a thickness from about 10 nm to about 100 nm which is capable of maximizing the efficiency of the white organic light emitting device.

As the blue light emitting material, DPVBi (1,4-bis(2,2′-diphenyl vinyl)benzene), NPB, etc having a band gap between 3.5 eV and 2.5 eV may be used.

As the first guest, a red light emitting material having a band gap between 2.2 eV and 1.7 eV, such as DCM (4-dicyanomethylene-2-methyl-6-(p-dimethylamino-styryl)-4H-pyran), DCJTB (4-(dicyanomethylene)-2-t-butyl-6-(1,1,7,7-tetramethyljulolidyl-9-enyl)-4H-ryran), DADB (4, 4′-diaminodibenzyl-2, 2′-disulfonic acid) etc., may be used, and is doped at a concentration such that blue energy does not move to the red first guest, for example, between 0.01 and 5%, and preferably of 0.05%.

As the second guest, a blue light emitting material having a band gap between 3.5 eV and 2.5 eV, such as DSA-Amine (amino-substituted distyrylarylene amine), Perylene, etc., may be used, and is doped at a concentration capable of obtaining optimal blue efficiency, for example, between 0.1 and 10%, and preferably of 5%.

An HBL 36 for confining the holes in the emission layer 35 is formed on the emission layer 35. The HBL 36 may make use of a material having a level of HOMO (highest occupied molecular orbital) energy higher than the emission layer 35, for example, BCP (2,9-dimethyl-4,7-diphenyl-1,10-phenanthroline), TAZ (3-(4-tert-butylphenyl)-4-phenyl-5-(4-biphenylyl)-1,2,4-triazole), etc. The material of BCP, TAZ, etc. has an HOMO energy level higher than the emission layer 35 by a range from about 0.5 eV to about 1.0 eV.

The HBL 36 is formed to a thickness smaller than a Forster energy transfer radius, for example, between 1 and 5 nm. This thickness is set to enable Forster energy transfer of excitons from the emission layer 35 to the ETL 37, so that the ETL 37 can have the luminescence properties. With regard to the Forster energy transfer radius, there is described in the document, for example X. G. Jacket et al., “Electrophosphorescence from a polymer guest-host system with an iridium complex as guest: Forster Energy Transfer and Charge Trapping,” Advanced Functional Materials 2003, 13, pp439-444.

An ETL 37 is formed on the HBL 36. The ETL 37 has a green luminescence property and makes it possible to efficiently transport electrons into the emission layer 35. The ETL 37 is preferably formed of a material having a green luminescence property, such as tris-(8-hydroxy quinoline aluminum) (Alq3), 4,7-diphenyl-1,10-phenanthroline (BPhen), etc.

An EIL 38 is formed on the ETL 37. An organic thin layer such as of 1,3,4-oxadiazole derivative (PBD), 4,7-diphenyl-1,10-phenanthroline (BPhen) or Li-doped BPhen, or an inorganic thin layer such as LiF, NaF, AlO or CsF is used as the EIL 38. Further, the EIL 38 is preferably formed of a material facilitating injection of the electrons from the cathode.

A cathode 39 is formed in a desired region on the EIL 38. The cathode 39 may be formed of Al, Ag, LiAl, Mg/Al, Mg/Ag, and so forth.

In order to obtain the white luminescence property using a general method, the orange light emitting material is deposited on the blue light emitting material, otherwise the red light emitting material is deposited on the sky blue light emitting material. However, in this case, the color reproduction is lowered due to the low luminescence property of the green light emitting material. Further, in order to simply implement the emission layer into a single layered structure, an orange guest is directly doped into a blue host, otherwise a red guest is directly doped into an sky blue host. In this case, the energy is easily transferred from the blue or sky blue host to the orange or red guest having a small energy band gap, so that it is difficult to emit white light.

Therefore, the present invention is designed to have blue and red luminescence properties by forming the blue light emitting material as the host and by forming the emission layer 35 into which the first guest capable of exhibiting the orange or red luminescence property is doped. It is possible to add the second guest capable of improving the efficiency of the blue light emitting material. Further, in order to improve the color purity being a problem in the two-wavelength white organic light emitting device, the HBL 36 is formed on the emission layer 35 to efficiently confine the holes in the emission layer to increase the luminescence efficiency. At this time, in order to enable the Forster energy transfer of excitons from the emission layer 35 to the ETL 37, the HBL 36 is formed thinner than the Forster energy transfer radius. As a result, the HTL 37 has a green luminescence property.

FIG. 2 shows a luminescence spectrum of a white organic light emitting device fabricated according to the present invention. A configuration of the white organic light emitting device used for the present measurement is formed as follows. Between the anode 32 of ITO and the cathode 39 of Al are deposited various materials of: MTDATA of 10 nm thickness as the HIL 33, NPB of 30 nm thickness as the HTL 34, DPVBi of 300 nm thickness as the emission layer 35 into which DADB of 0.05 wt % and DSA-Amine of 3.0 wt % are doped, BCP of 3 nm thickness as the HBL 36, Alq of 30 nm thickness as the ETL 37, and Lif of 1 nm thickness as the EIL 38. The luminescence properties of the white organic light emitting device having the above-mentioned configuration are measured by a Minolta CS1000 spectrometer, and the measured luminescence spectrum is shown in FIG. 2. To the purpose of this measurement, a current of 20 mA/cm² was applied between the anode 32 and the cathode 39. As set forth above, the white organic light emitting device exhibits excellent white luminescence property that an entire visual range of luminescence properties are exhibited in spite of the monochromatic emission configuration.

In the general white organic light emitting device, two emission layers having a complementary color relationship are deposited or three emission layers of three primary colors are deposited to thereby generate the white luminescence property. However, in this case, it has a trouble in that a multi-layered organic thin layer should be deposited and a problem that the luminescence efficiency is deteriorated.

The present invention implements the white organic light emitting device which is simple in configuration and has a single emission layer, thereby accomplishing easy fabrication and reduction of manufacturing costs. The white organic light emitting device of the present invention can realize a universal white organic light emitting device capable of obtaining a high efficiency of white color, due to excellent color production caused by the three-wavelength white color. Further, when applying the white organic light emitting device of the present invention, it is easy to implement a liquid crystal display (LCD) which includes a white light backlight and a color filter, an illumination board, a white organic LED, etc.

While the invention has been shown and described with reference to certain exemplary embodiments thereof, it will be understood by those skilled in the art that various changes in form and details may be made therein without departing from the spirit and scope of the invention as defined by the appended claims.

1. A white organic light emitting device comprising:
an anode and an cathode to which a bias is applied; and
an emission layer into which a host having a blue luminescence property and a first guest exhibiting an orange or red luminescence property are doped, a hole blocking layer for confining holes in the emission layer, and an electron transport layer having a green luminescence property,
wherein the emission layer, the hole blocking layer, and the electron transport layer are stacked-between the anode and the cathode.

2. The white organic light emitting device according to claim 1, wherein a second guest capable of improving efficiency of the blue light emitting material is additionally doped.

3. The white organic light emitting device according to claim 1, wherein the blue light emitting material is any one of DPVBi and NPB having a band gap between 3.5 eV and 2.5 eV.

4. The white organic light emitting device according to claim 1, wherein the first guest is any one of DCM, DCJTB and DADB having a band gap between 2.2 eV and 1.7 eV, and is doped at a concentration between 0.01 and 5%.

5. The white organic light emitting device according to claim 1, wherein the second guest is any one of DSA-Amine and Perylene having a band gap between 3.5 eV and 2.5 eV, and is doped at a concentration between 0.1 and 10%.

6. The white organic light emitting device according to claim 1, wherein a hole injection layer and a hole transport layer are additionally interposed between the anode and the emission layer.

7. The white organic light emitting device according to claim 1, wherein an electron injection layer is further formed on the hole transport layer.

8. The white organic light emitting device according to claim 1, wherein the hole blocking layer is formed of a material having a level of highest occupied molecular orbital (HOMO) energy higher than the emission layer.

9. The white organic light emitting device according to claim 8, wherein the material is any one of BCP and TAZ.

10. The white organic light emitting device according to claim 1, wherein the hole blocking layer is formed to a thickness smaller than a Forster energy transfer radius so as to enable Forster energy transfer of excitons from the emission layer to the electron transport layer.

11. The white organic light emitting device according to claim 10, wherein the hole blocking layer is formed to a thickness from 1 to 5 nm.

12. A white organic light emitting device having a hole injection layer, a hole transport layer, an emission layer, a hole blocking layer, an electron transport layer and an electron injection layer which are deposited between an anode and a cathode on a substrate, comprising:
a host having a blue luminescence property and a first guest having any one of orange and red luminescence properties doped into the emission layer; and
a material with a green luminescence property formed in the electron transport layer.

13. The white organic light emitting device according to claim 12, wherein the hole blocking layer is formed to a thickness smaller than a Forster energy transfer radius so as to enable Forster energy transfer of excitons from the emission layer to the electron transport layer.

14. The white organic light emitting device according to claim 12, wherein a second guest capable of improving efficiency of the blue light emitting material is additionally doped.
